(19) United States
(12) Patent Application Publication
(10) Pub. No.: US 2025/0210378 A1
(43) Pub. Date: Jun. 26, 2025

(54) SYSTEM AND METHOD FOR DYNAMIC LOADLOCK PRESSURE CONTROL

(71) Applicant: Axcelis Technologies, Inc., Beverly, MA (US)

(72) Inventor: John Baggett, Amesbury, MA (US)

(21) Appl. No.: 18/978,031

(22) Filed: Dec. 12, 2024

Related U.S. Application Data
(60) Provisional application No. 63/612,390, filed on Dec. 20, 2023.

(51) Int. Cl. H01L 21/67

(52) U.S. Cl. CPC H01L 21/67017

(57) ABSTRACT

A workpiece processing system has a process chamber for processing a workpiece within a process environment at vacuum pressure, defining a process time. A loadlock chamber defines a loadlock volume and has a vacuum isolation valve providing selective fluid communication between the loadlock volume and the process environment. The vacuum isolation valve permits the workpiece to transfer between the loadlock volume and the process environment. An atmospheric isolation valve provides fluid communication between the loadlock volume and atmosphere and selectively permits the workpiece to transfer between the loadlock volume and atmosphere. A vent gas control device selectively controls a pressure or flow rate of a vent gas to the loadlock volume, defining a vent time by a change from the vacuum pressure to atmospheric pressure. A controller controls the vent gas control device based on a critical path defined by the longer of the process time and the vent time.

### REFERENCE TO RELATED APPLICATIONS

This application claims the benefit of U.S. Provisional Application Ser. No. 63/612,390 filed Dec. 20, 2023, entitled, “SYSTEM AND METHOD FOR DYNAMIC LOADLOCK PRESSURE CONTROL,” the contents of all of which are herein incorporated by reference in their entirety.

### FIELD

The present disclosure relates generally to workpiece processing systems and methods for processing workpieces, and more specifically to a system, apparatus, and method for increasing throughput associated with a loadlock chamber used in ion implantation.

### BACKGROUND

In semiconductor processing, many operations may be performed on a single workpiece or semiconductor wafer. In general, each processing operation on a workpiece is typically performed in a particular order, wherein each operation waits until completion of a preceding operation, thus affecting the time at which the workpiece will become available for a subsequent processing step. Tool productivity or throughput for relatively short processes performed under vacuum, such as ion implantation, can be severely limited if the process flow leading to the processing location is interrupted by sequential events associated with such processing. For example, operations such as an exchange of workpieces between transport carriers or storage cassettes and the processing system, a transfer of the workpiece from an atmospheric environment into an evacuated environment of an implantation chamber of the processing system, and an orientation of the workpiece (e.g., notch alignment) within the evacuated environment, can have a significant impact on tool productivity.

Processing of a workpiece, such as ion implantation, for example, is typically performed at a reduced pressure within an implantation chamber, wherein ions are generally accelerated along a beam line, and wherein the ions enter the evacuated implantation chamber and strike the workpiece in a predetermined manner. Several operations are typically performed leading up to the implantation in order to introduce the workpiece into the implantation chamber, as well as to properly position and orient the workpiece with respect to the ion beam within the implantation chamber. For example, the workpiece is transferred via a robot from an atmospheric cassette or storage device into a load lock chamber, wherein the load lock chamber is subsequently evacuated in order to bring the workpiece into the processing environment of the ion implanter. The cassette or storage device, for example, may be delivered to the ion implanter via a conveyor system or other type of delivery.

U.S. Pat. No. 5,486,080 to Sieradzki, for example, details a system for transferring semiconductor wafers for vacuum processing. The system employs two wafer transport robots for moving wafers from two load locks past a processing station. Additional patents relating to serial end stations are U.S.

U.S. Pat. Nos. 6,350,097, 6,555,825, and 5,003,183. Further, commonly-owned U.S. Pat. No. 7,010,388 to Mitchell et al. details a wafer handling system for handling one or two wafers at a time.

It is generally desirable for the workpiece handling system to have high throughputs in order to reduce the cost of ownership of the processing system. This is especially true in an ion implantation process when a duration of the implantation is very short compared to the time needed to transfer a new workpiece from a Front Opening Unified Pod (FOUP) to the implantation chamber and back to the FOUP. The actual ion implantation into a workpiece for a low dose implant, for example, has a short duration, wherein implant times can be less than 5 seconds.

However, particle contamination during workpiece transfer is also a concern, whereby a speed at which the pressure is raised in the loadlock chamber can disturb particulate contaminants within the loadlock chamber. Reducing pressure during a loadlock vent routine can improve particle performance, however, such a reduction in pressure has a cost in increased vent times, thus deleteriously affecting throughput.

### SUMMARY

The present disclosure overcomes the limitations of the prior art by providing a system, apparatus, and method for transferring workpieces between atmospheric and vacuum environments, while maximizing throughput and minimizing costs of ownership associated with the systems. More particularly, the present disclosure provides a system and method for optimizing particle contamination concerns in light of workpiece throughput.

Accordingly, the following presents a simplified summary of the disclosure in order to provide a basic understanding of some aspects of the disclosure. This summary is not an extensive overview of the disclosure. It is intended to neither identify key or critical elements of the invention nor delineate the scope of the invention. Its purpose is to present some concepts of the disclosure in a simplified form as a prelude to the more detailed description that is presented later.

In accordance with one example of the present disclosure, a workpiece processing system is provided and comprises a process chamber configured for processing a workpiece within a process environment at a vacuum pressure. Processing of the workpiece within the process environment of the process chamber, for example, defines a process time.

A loadlock chamber is further provided, whereby the loadlock chamber defines a loadlock volume therein. The loadlock chamber, for example, comprises a vacuum isolation valve configured to provide selective fluid communication between the loadlock volume and the process environment. The vacuum isolation valve, for example, is further configured to selectively permit the workpiece to transfer between the loadlock volume and the process environment. The loadlock chamber, for example, further comprises an atmospheric isolation valve configured to provide selective fluid communication between the loadlock volume and an atmospheric environment at an atmospheric pressure. The atmospheric isolation valve, for example, is further configured to selectively permit the workpiece to transfer between the loadlock volume and the atmospheric environment.

The workpiece processing system, for example, further comprises a vent gas control device configured to selectively control one or more of a pressure and a flow rate of a vent gas from a vent gas source to the loadlock volume, whereby a vent time is defined by a change from the vacuum pressure to the atmospheric pressure within the loadlock volume. Furthermore, a controller is provided and configured to control the vent gas control device based, at least in part, on a critical path defined by the longer of the process time and the vent time.

The above summary is merely intended to give a brief overview of some features of some embodiments of the present disclosure, and other embodiments may comprise additional and/or different features than the ones mentioned above. In particular, this summary is not to be construed to be limiting the scope of the present application. Thus, to the accomplishment of the foregoing and related ends, the disclosure comprises the features hereinafter described and particularly pointed out in the claims. The following description and the annexed drawings set forth in detail certain illustrative embodiments of the disclosure. These embodiments are indicative, however, of a few of the various ways in which the principles of the disclosure may be employed. Other objects, advantages and novel features of the disclosure will become apparent from the following detailed description of the disclosure when considered in conjunction with the drawings.

### BRIEF DESCRIPTION OF THE DRAWINGS

FIG. 1 illustrates a block diagram of a workpiece processing system in accordance with various example aspects of the present disclosure.

FIG. 2 is a schematic representation of a vent system for a loadlock chamber in accordance with various example aspects of the present disclosure.

FIG. 3 is a block diagram illustrating an exemplary method for optimizing throughput and reducing particle contamination according to another example aspect of the disclosure.

FIG. 4 is a block diagram illustrating a control system configured to control a workpiece processing system in accordance with another example aspect.

### DETAILED DESCRIPTION

The present disclosure is directed generally toward semiconductor processing systems and methods, and more particularly, to a system for controlling a venting of a loadlock chamber for the semiconductor processing system, whereby particle contamination and throughput are optimized based on a critical path of a process flow for the semiconductor processing system.

Accordingly, the present disclosure will now be described with reference to the drawings, wherein like reference numerals may be used to refer to like elements throughout. It should be understood that the description of these aspects are merely illustrative and that they should not be interpreted in a limiting sense. In the following description, for purposes of explanation, numerous specific details are set forth in order to provide a thorough understanding of the present disclosure. It will be evident to one skilled in the art, however, that the present disclosure may be practiced without these specific details.

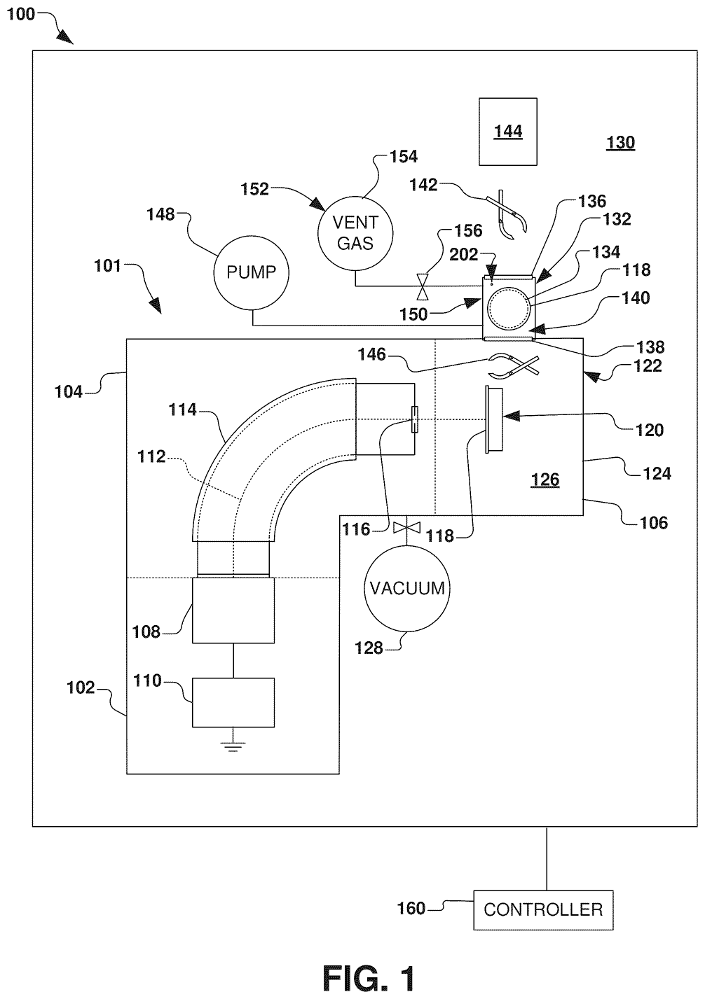

In order to gain a broader understanding of the invention and in accordance with various aspects of the present disclosure, FIG. 1 illustrates an example of a workpiece processing system 100. While the workpiece processing system 100 in the present example comprises an exemplified ion implantation system 101, it will be appreciated that various other types of vacuum-based semiconductor processing systems are also contemplated, such as for example, plasma processing systems, or other semiconductor processing systems. The ion implantation system 101, for example, comprises a terminal 102, a beamline assembly 104, and an end station 106.

Generally speaking, an ion source 108 in the terminal 102 is coupled to a power supply 110 to ionize a dopant gas into a plurality of ions and to form an ion beam 112. The ion beam 112 in the present example is directed through a mass analysis apparatus 114, and out an aperture 116 towards the end station 106. In the end station 106, the ion beam 112 bombards a workpiece 118 (e.g., a substrate such as a semiconductor wafer, a display panel, etc.), which is selectively clamped or mounted to a workpiece chuck 120. The workpiece chuck 120, for example, may comprise an electrostatic chuck (ESC), a thermal chuck, a mechanical clamp, or other workpiece support, wherein the workpiece chuck is configured to selectively support the workpiece 118 in the end station 106.

Once embedded into the lattice of the workpiece 118, the implanted ions change the physical and/or chemical properties of the workpiece. Because of this, ion implantation is used in semiconductor device fabrication and in metal finishing, as well as various applications in materials science research.

The ion beam 112 of the present disclosure can take any form, such as a pencil or spot beam, a ribbon beam, a scanned beam, or any other form in which ions are directed toward end station 106, and all such forms are contemplated as falling within the scope of the disclosure.

According to one exemplified aspect, the end station 106 comprises a process chamber 122, such as a vacuum chamber 124, wherein a process environment 126 is associated with the process chamber. The process environment 126 (e.g., a high vacuum environment) generally exists within the process chamber 122, and in one example, comprises a vacuum produced by a vacuum source 128 (e.g., a vacuum pump) coupled to the process chamber and configured to substantially evacuate the process chamber.

In order to transfer workpieces 118 between an atmospheric environment 130 at atmospheric pressure and the process environment 126 of the process chamber 122, a loadlock chamber 132 is operably coupled to the process chamber. The loadlock chamber 132, for example, comprises a workpiece support 134 configured to selectively support the workpiece 118 within the loadlock chamber. The present disclosure contemplates any number of loadlock chambers 132 operably coupled to the process chamber 122, any of the loadlock chambers may be further configured as a dual loadlock chamber (not shown), such that two workpieces 118 may be individually or collectively supported within, loaded into, or unloaded from the dual loadlock chamber, as will be appreciated by one of ordinary skill in the art.

The loadlock chamber 132, for example, comprises an atmospheric loadlock valve 136 (e.g., also called an atmospheric loadlock door) and a vacuum loadlock valve 138 (e.g., also called a vacuum loadlock door). The atmospheric loadlock valve 136 and the vacuum loadlock valve 138, for example, are configured to selectively isolate a loadlock environment 140 within the loadlock chamber 132 from the respective atmospheric environment 130 and the process environment 126. The atmospheric loadlock valve 136, for example, is further configured to selectively permit a transfer of the workpiece 118 between the workpiece support 134 within the loadlock chamber 132 and the atmospheric environment 130 external to the loadlock chamber. For example, an atmospheric workpiece transfer apparatus 142 (e.g., a transfer robot) can be configured to transfer the workpiece 118 from the workpiece support 134 to a workpiece carrier 144 (e.g., a front opening unified pod or FOUP) in the atmospheric environment.

The vacuum loadlock valve 138, for example, is further configured to selectively permit a transfer of the workpiece 118 between the workpiece support 134 and the process environment 126, such as to and from the workpiece chuck 120, and via a vacuum workpiece transfer apparatus 146 (e.g., a transfer robot). One or more of the atmospheric workpiece transfer apparatus 142 and the vacuum workpiece transfer apparatus 146, for example, may comprise one or more transfer robots.

In accordance with one example, a loadlock pump 148 is provided in selective fluid communication with the loadlock chamber 132, whereby the loadlock pump is configured to selectively evacuate a loadlock volume 150 defined within the loadlock chamber 132. The loadlock pump 148 for example, is configured to selectively evacuate the loadlock volume 150 and to lower a pressure associated with the loadlock environment 140 from atmospheric pressure associated with the atmospheric environment 130 to the vacuum pressure associated with the process environment 126 when the atmospheric loadlock valve 136 and the vacuum loadlock valve 138 are closed. Once the pressure within the loadlock environment 140 is at approximately the same pressure as the vacuum environment, the vacuum loadlock valve 138 may be opened for transfer of the workpiece 118 to the process environment 126.

Further, in accordance with the present disclosure, a vent gas supply system 152 is provided. The vent gas supply system 152, for example, comprises a vent gas source 154 configured to selectively deliver a vent gas, such as pressurized nitrogen gas, to the loadlock volume 150. The vent gas supply system 152, for example, further comprises a vent gas control device 156 in selective fluid communication with the vent gas source 154 and the loadlock volume 150, whereby the vent gas control device is configured to control one more of a pressure, a flow rate, and a velocity of the vent gas, as will be discussed in greater detail infra. The vent gas control device 156, for example, can comprise a mass flow controller, a pressure flow controller, a pressure regulator, a velocity regulator, a needle valve, or the like.

In accordance with another exemplified aspect, a controller 160 is further operably coupled to the workpiece processing system 100, and configured to provide control of one or more of the components within the workpiece processing system. The controller 160, for example, can be configured to provide overall control of the ion implantation system 101. The controller 160, for example, can further provide control of the loadlock chamber 132, the loadlock pump 148, and the vent gas supply system 152. Accordingly, the controller 160 can be configured to control various aspects of the ion implantation system 101 in order to implant ions into the workpiece 118, transfer workpieces between the atmospheric environment and the process environment, and to further control a timing, thereof.

The present disclosure appreciates that the workpiece processing system 100 can comprise various semiconductor processing systems configured to perform various process on various types of workpieces 118, whereby the loadlock chamber 132 can be utilized for transferring the workpiece between the process environment 126 and the atmospheric environment 130. In one example, the workpiece 118 is loaded in the loadlock chamber 132 from the atmospheric environment 130, and the loadlock chamber is evacuated or otherwise pumped down from atmospheric pressure to a vacuum pressure associated with the process environment 126 via the loadlock pump 148. The workpiece 118 is then removed from the loadlock chamber 132 and transferred to the process chamber 122 via the vacuum workpiece transfer apparatus 146 (e.g., one or more robots), whereby the workpiece undergoes semiconductor processing (e.g., ion implantation) in the process chamber. The workpiece 118 can be transferred back to loadlock chamber 132 after processing, whereby the loadlock chamber is subsequently vented via the vent gas supply system 152 in order to return the loadlock chamber to atmospheric pressure for removal of the processed workpiece and be readied for subsequent workpieces in order to repeat the process.

Accordingly, in some instances, the loadlock chamber 132 can be considered to be in a so-called “critical path” of workpiece processing, whereby throughput of workpieces 118 through the workpiece processing system 100 can be affected by the time taken for the evacuation and venting of the loadlock chamber. A process that is in the critical path, for example, is considered to be a process that impacts a total time for the process to complete. For example, when processes are performed in parallel, the process that is in the critical path is typically the process that takes the longest to perform.

The loadlock chamber 132, for example, can comprise a dual-workpiece loadlock chamber (not shown), for example, in order to increase throughput of workpieces 118, whereby two workpieces can be transferred into and out of the dual-workpiece loadlock chamber in order to provide various efficiencies, thus possibly removing the transfer of workpieces between the atmospheric environment 130 and the process environment 126 from the critical path of workpiece processing. Further, multiple loadlock chambers (not shown) can be utilized to provide additional throughput efficiencies, such that one loadlock chamber may be vented while another loadlock chamber is evacuated, or vice-versa in order increase throughput and potentially remove the transfer from the critical path.

In semiconductor processing that incorporates ion implantation, for example, various configurations of ion implantation system 101 can be utilized, such as configurations for performing high-current implants, high-energy implants, or other implants having various so-called process recipes associated with various implant conditions, whereby a time taken by the actual ion implantation into the workpiece 118 in the process chamber 122 can vary based on the particular type of implant or process recipe selected. As such, the present disclosure appreciates that the particular semiconductor process being performed on the workpiece can thus also be in the critical path.

For example, a particular ion implantation into one workpiece 118 can be performed in parallel with the evacuation or venting of the loadlock chamber 132 associated with the transfer of another workpiece between the atmospheric environment 130 and the process environment 126. Accordingly, either of the processing of workpieces 118 in the process chamber 122 or the evacuation or venting of the loadlock chamber 132 can be in the critical path, depending on the particular semiconductor processing being performed on the workpieces.

For high energy implants, for example, the evacuation or venting of the loadlock chamber 132 can be in the critical path due to the relatively fast process of implanting high energy ions into the workpiece 118. As such, a time taken for the high energy ion implantation process can be less than a time taken for the transfer of workpieces via the loadlock chamber 132 between the atmospheric environment 130 and the process environment 126. For high current implants, on the other hand, the ion implantation, itself, can be in the critical path due, at least in part, to the high current and high dosage of ions implanted into the workpiece 118. In such a high current implant, a time taken for the high current ion implantation process can be substantially longer than a time taken for the transfer of workpieces 118 between the atmospheric environment 130 and the process environment 126.

While implantation times can vary from several seconds to several minutes based on the type of implantation and/or process recipe, conventional ion implantation systems are not known to vary the time for venting the loadlock chamber 132 based on the respective time for ion implantation into the respective workpieces 118. Conventionally, the focus of maximizing throughput has centered on removing any transportation of the workpiece between the atmospheric environment and the process environment from the critical path, whereby any time taken for evacuating or venting a conventional loadlock chamber has been traditionally minimized.

The present disclosure appreciates that processing of one workpiece 118 can occur in parallel with venting of the loadlock chamber 132 containing another workpiece that has already been processed. As such, the present disclosure appreciates that the loadlock chamber 132 can be advantageously vented from the vacuum pressure associated with the process environment 126 to atmospheric pressure associated with the atmospheric environment 130, such that the time taken in venting of the loadlock chamber can be increased with respect to conventional times, while still not being in the critical path of the process. The disclosure further presently appreciates that the conventional fast venting of the loadlock chamber 132 can be disruptive or disturbing to particles that may be present within the loadlock chamber. For example, a high-pressure vent gas (e.g., pressurized nitrogen gas) is flowed into a conventional loadlock chamber to quickly vent the loadlock chamber to atmospheric pressure. Such a high-pressure vent gas can have a negative impact on particle contamination associated with the conventional loadlock chamber, however, as contaminant particles that may be present within the loadlock chamber can be disrupted and transferred to the workpiece.

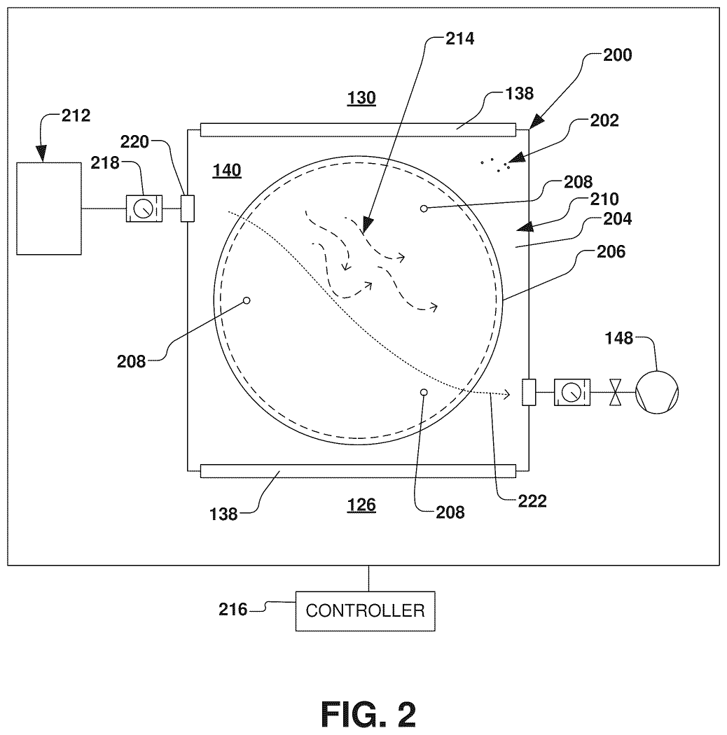

For example, FIG. 2 illustrates a loadlock chamber 200 in accordance with various aspects of the present disclosure. The loadlock chamber 132 of FIG. 1, for example, may comprise various features of the loadlock chamber 200 shown in FIG. 2. As illustrated in FIG. 2, contaminant particles 202 are illustrated as having collected on a floor 204 of the loadlock chamber 200 over time. The contaminant particles 202 may alternatively be present on any of a workpiece 206, on a workpiece support 208 for the supporting the workpiece within a loadlock volume 210 of the loadlock chamber, or on other features within the loadlock chamber. A vent gas source 212, for example, can comprise a high-pressure vent gas (e.g., nitrogen gas) that is selectively fluidly coupled to the loadlock chamber 200. It is to be appreciated that, should the vent gas source 212 quickly introduce the high-pressure vent gas to the loadlock chamber 200 at a high flow rate or a high pressure, such as described above, turbulent flow (illustrated as dashed lines 214) associated with the high flow rate and/or high pressure of the vent gas can disrupt or move the contaminant particles 202 within the loadlock chamber 200 and subsequently re-deposit the particles on the workpiece 206, thus potentially leading to defects.

The present disclosure appreciates that in an example when a maximum throughput through the ion implantation system 101 of FIG. 1 is desired, and where the implantation of ions into the workpiece 118 takes a minimal amount of time (e.g., 2-3 seconds), such a fast venting of the loadlock chamber 200 of FIG. 2 can be advantageous for throughput, as the vent time (e.g., less than approximately 2 seconds) taken for venting of the loadlock chamber can be in the critical path. In such an instance, a fast venting of the loadlock chamber 200 can be desirable for throughput, regardless of a possibility of particle contamination of the workpiece 206, such that the time taken for venting of the loadlock chamber is minimized. In such an instance, the contaminant particles 202 can be removed through increased preventative maintenance of the loadlock chamber 200.

However, for longer processes performed on the workpiece 206, such as an ion implantation requiring an extended amount of time (e.g., 10-30 seconds or greater), the ion implantation process can be in the critical path, whereby the aforementioned fast venting of the loadlock chamber 200 described above is not required to maintain a desired throughput. For example, in a process recipe requiring 30 seconds for the implantation of ions (called the “implant time”) into the workpiece 118 in the process chamber 122 of FIG. 1, venting of the loadlock chamber 132 can be advantageously extended to decrease the flow and/or pressure of the vent gas introduced to the loadlock chamber, thus decreasing a likelihood of disturbing the contaminant particles 202 within the loadlock chamber, while not affecting overall throughput.

The implant time, for example, is associated with various attributes of the process recipe, such as a dosage of ions desired for the implant, a beam current of the ion beam 112 impacting the workpiece 118, as well as a scan velocity and a number of scans of the ion beam with respect to the workpiece, among other variables associated with the ion beam and/or process chamber 122. An initial implant time, for example, can be calculated or otherwise determined based on the attributes of the process recipe, whereby the initial implant time can be utilized to determine an initial vent time for the loadlock chamber 132. The initial vent time, for example, is determined such that the venting of the loadlock chamber 132 is not in the critical path of the process, whereby the initial vent time is maximized, but less than or equal to the initial implant time. The initial vent time, for example, can be a predetermined percentage of the initial implant time. Alternatively, the initial vent time can be determined by subtracting a predetermined buffer time from the initial implant time in order to ensure that the venting of the loadlock chamber 132 is not in the critical path.

The initial vent time, for example, can be utilized by a controller 216 to determine and provide a control one or more of a flow rate and a pressure of the vent gas provided from the vent gas source 212 to the loadlock chamber 200. Such a control of the flow rate and/or pressure of the vent gas from the vent gas source 212 thus controls the time taken for venting of the loadlock chamber 200 from the process pressure associated with the process environment 126 to approximately atmospheric pressure associated with the atmospheric environment 130. For example, the flow rate and/or pressure of the vent gas can be controlled by a vent gas control device 218 such as a mass flow controller, a pressure flow controller, a pressure regulator, a velocity regulator, a needle valve, or the like. A pressure sensor 220 can be further provided, whereby pressure feedback can be provided to the controller 216.

Accordingly, the speed and flow rate associated with venting the loadlock chamber 200 to atmospheric pressure can be controlled to correlate the vent time with the process time. For example, for long process times, such as for high current implants, the pressure or flow rate of the vent gas can be minimized or otherwise controlled to allow the loadlock chamber 200 to vent to atmospheric pressure at a slower rate, thus yielding a greater degree of a laminar flow 222, while at the same time, maintaining the vent time at less than the implantation time. As such, the process of venting of the loadlock chamber 200 is kept from being in the critical path of the process. Thus, there is less of a potential for dislodging, shifting, or otherwise disturbing the contaminant particles 202 within the loadlock chamber 200 by such a control of the pressure or flow rate of the vent gas associated with the venting to atmospheric pressure.

For short process times, such as for high energy implants, the pressure or flow rate of the vent gas can be maximized to keep the implantation process from being in the critical path, thus providing the desired throughput. Such a control of the pressure and flow rate of the vent gas in a process having a short implant time can still maximize the vent time. However, if throughput is the primary concern, the upper limit of the vent time can be approximately equal to the process time.

Accordingly, the present disclosure maximizes the vent time without deleteriously affecting throughput based on the particular processing and process recipes. Further, feedback from the actual process time can be utilized to further control the pressure and/or flow rate of the vent gas to match that actual process time (e.g., including the predetermined buffer time) for subsequent workpiece processing.

The present disclosure further appreciates that the vent time can be further determined via a characterization of the workpiece processing system 100 of FIG. 1, such that various characteristics of the workpiece processing system can be utilized to maximize the vent time while maintaining the desired throughput of workpieces 118 through the workpiece processing system. For example, characteristics such as the loadlock volume 150 of the loadlock chamber 132, flow or pressure capabilities of the vent gas control device 156, maximum speeds of transfer robots 142, 146, speeds of isolation valves or loadlock doors 136, 138, or other characteristics of other devices associated with the transport of workpieces 118 through the workpiece processing system 100 can be utilized to determine the maximum vent time to reduce particle contamination while maintaining the desired throughput. Such a characterization of the workpiece processing system 100 can be achieved mathematically (e.g., volumetric calculations associated with flow of the vent gas through the loadlock volume 150 of the loadlock chamber 132), or via a lookup table or other characterization scheme.

The present disclosure contemplates various process actions being performed in parallel with the venting of the loadlock chamber 132, such as the implantation process, as well as various workpiece transfer actions or other process actions. Workpiece transfer actions, for example, can comprise robotically transferring a workpiece 118 from the loadlock chamber 132 to the workpiece chuck 120 or other workpiece support apparatus (e.g., a heating station, cooling station, transfer station, etc.) within the process environment 126. Other example process actions can comprise workpiece alignment or workpiece presence verifications, as well as other pre-implantation or post-implantation actions. Accordingly, such process actions being performed in parallel with the venting of the loadlock chamber 132 can contribute to the determination of the vent time and control of the pressure and/or flow rate of the vent gas into the loadlock chamber. For example, robotic transfer speeds can further contribute to the determination of the vent time to maximize the vent time without the vent time ever being in critical path of workpiece throughput.

In one example, the pressure and/or flow rate of the vent gas can be maximized to allow for maximum throughput of workpieces (e.g., 500 workpieces per hour), whereby the vent time for the loadlock chamber 132 is minimized (e.g., a vent time of approximately 2 seconds), whereby the extent of minimization of the vent time can be limited to the architecture of the loadlock chamber and transfer mechanisms, etc. A high maximum throughput, for example, can be desirable for high energy ion implanters, such as the Purion XE family of ion implantation systems manufactured by Axcelis Technologies, Inc. of Beverly, MA, whereby the process time is less than or equal to the minimum vent time. For systems having longer process times, such as high current ion implanters Purion H family of ion implantation systems manufactures by Axcelis Technologies, Inc., throughput is generally limited by the implant time, whereby vent time can be increased to accommodate the longer process time, thus providing advantages for reducing particle contamination.

Accordingly, the vent time can be optimized based on the process time for any particular process. When throughput is the primary concern, the loadlock venting can be in the critical path. Thus, vent time can be minimized in order to minimize any impact of the loadlock venting being in the critical path of processing. When the loadlock venting is not in the critical path, however, the vent time can be maximized, while being less than or equal to the process time, such that pressures and/or flow rates of the vent gas can be advantageously lowered to reduce particle contamination without deleteriously affecting throughput. Thus, the present disclosure provides a flexible control system that is applicable to many varied semiconductor processing systems having varied throughput limitations or requirements, while providing the ability to limit issues associated particle contamination.

Once one or more workpieces are processed through the processing system, either the same recipe and vent times can be utilized, or data associated with the processing system and vent times can be utilized as feedback for further determining subsequent vent times. Historical data (e.g., a lookup table) can be utilized to initially characterize the vent time for the system, or the vent time can be calculated or other determined based on properties of the system, as discussed above. As such, the pressure and/or flow rate of the vent gas supplied to the loadlock chamber can be controlled based on the characterization or the feedback from the data associated with the processing system.

The present disclosure further contemplates variations in pressures of the vent gas associated with the vent gas source 154 that may be available in a fabrication facility, or across a plurality of fabrication facilities. For example, one fabrication facility can be configured to provide the vent gas source 154 comprising nitrogen at 90 psi, while another fabrication facility can be configured to provide nitrogen at a maximum pressure of 60 psi. The above-described characterization, for example, can take such a variation in vent gas pressures into account so as to control the respective workpiece processing system 100 and provide a consistent venting of the respective loadlock chambers 132, while maintaining the desired throughput and limiting particle contamination. The characterization of the loadlock chamber 132, for example, can further define a minimum vent time, whereby the minimum vent time is considered to be the lowest amount of time considered to be acceptable for venting the loadlock chamber without deleterious issues such as displacement of the workpiece 118.

The present disclosure thus provides a balance of having optimal throughput while further providing optimal particle performance based on the optimal throughput. For example, the present disclosure contemplates instances where contaminant particles 202 are present in the loadlock chamber 132, where conventionally, such a presence of contaminant particles could be transferred to the workpiece due to the conventional venting routine. In order to mitigate such particle contamination in the past, the processing system would have been taken out of production for preventive maintenance, whereby the loadlock chamber would be opened to atmosphere, cleaned and wiped down, or otherwise maintained, thus losing productivity due to said maintenance.

However, in accordance with the present disclosure, when operating the workpiece processing system 100 having a process time that is greater than the minimum vent time, the pressure and/or flow rate of the vent gas can be advantageously lowered, whereby contaminant particles 202 that may exist within the loadlock chamber 132 are not generally disturbed, thus not transferring the contaminant particles to the workpiece 118 and requiring the additional preventive maintenance. By not disturbing the contaminant particles 202 within the loadlock chamber 132, a time between preventive maintenance procedures can be extended, thus lowering the cost of ownership, and producing uptime benefits. Further, the time between preventive maintenance procedures can be modified based on particle performance.

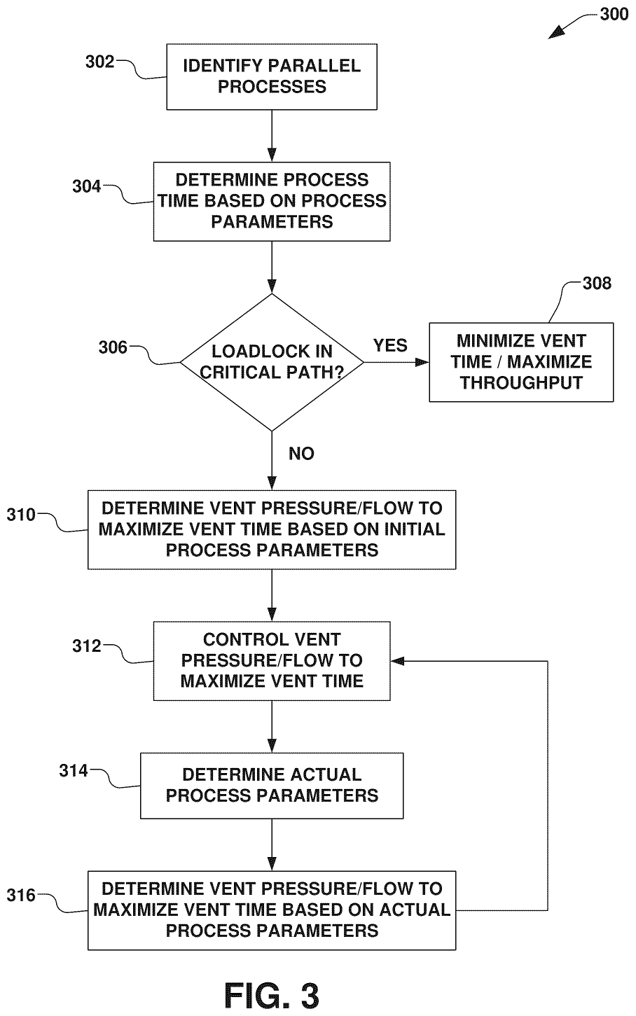

FIG. 3 illustrates an example methodology for optimizing vent times for various semiconductor processes. It should be noted that while exemplary methods are illustrated and described herein as a series of acts or events, it will be appreciated that the present disclosure is not limited by the illustrated ordering of such acts or events, as some steps may occur in different orders and/or concurrently with other steps apart from that shown and described herein, in accordance with the disclosure. In addition, not all illustrated steps may be required to implement a methodology in accordance with the present disclosure. Moreover, it will be appreciated that the methods may be implemented in association with the systems illustrated and described herein as well as in association with other systems not illustrated.

The method 300 shown in FIG. 3, for example, begins with act 302, whereby parallel processes are identified in the workpiece processing system. The identification of parallel processes in act 302, for example, identifies potential critical paths in the process. For example, parallel processes of ion implantation and loadlock chamber venting can be identified as being performed in parallel, whereby the process that takes a longer amount of time can be considered the critical path. Multiple processes, such as workpiece transfers, aligning processes, or workpiece verification processes may be further identified as being a parallel process, whereby each process may be considered individually, or grouped with other processes to determine potential critical paths of the process.

In act 304, a process time is determined, whereby the process time is based on process parameters associated with the workpiece processing system. The process parameters, for example, can be a process recipe for processing of the workpiece, such as ion implantation parameters including desired beam current, implantation dose, number of scans of the ion beam, etc. Further, the process parameters may comprise a characterization of various components of the workpiece processing system, such as speeds of transferring workpieces, opening and closing of valves, cooling or heating times, or the like. Additionally, process parameters can comprise a desired process throughput based on capabilities of the workpiece processing system.

A determination is made in act 306 as to whether the loadlock chamber, including the process of venting of the loadlock chamber, is in the critical path of the processing of workpieces through the workpiece processing system. If the loadlock chamber venting process takes longer than the ion implantation process, for example, the loadlock chamber is considered to be in the critical path in act 308, whereby in order to maximize throughput, the venting time is minimized, assuming particle contamination concerns are acceptable due at least in part to the flow rate of the vent gas through the loadlock chamber, thus further defining the minimum vent time.

If the determination made in act 306 is that the loadlock chamber is not in the critical path of the process, a determination of the vent pressure and/or flow of the vent gas for a maximum vent time is made based on initial process parameters in act 310. The vent time, for example, can be determined as a percentage (e.g., 90%) of the time taken for any parallel processes that were determined in act 302. The initial process parameters of act 310, for example, can comprise an initial calculation or estimate of the workpiece transfer times, implant times based on the process recipe, and any other process steps associated with processing of the workpiece into and out of the process chamber.

In act 312, the pressure and/or flow of the vent gas is controlled in accordance with the determination made in act 310, whereby the vent time is maximized based, and particle contamination is minimized. In act 314, a determination of actual process parameters is made. As opposed to the initial process parameters that were used in the determination made in act 310, the actual process parameters that are determined in act 314 comprise measured times for actual processes performed on past workpieces, such as the ion implantation, workpiece transfer, or other processes. As such, in act 316, the pressure and/or flow of the vent gas is again determined based on the actual process parameters, thus fine tuning the process. The method 300 then proceeds again to act 312, whereby the pressure and/or flow of the vent gas is controlled in accordance with the determination made in act 316.

For example, as conditions in the workpiece processing system change, such as an implant time being shorter or transfer time being longer than experienced for previous workpieces, times for all processes that are performed in parallel can be managed, such that the vent time can be adjusted via the vent gas supply system 152 (e.g., the controller 160 controlling the vent gas control device 156). For example, the vent gas supply system 152 can control the vent time to match or be predetermined percentage (e.g., 90%) of the process time for the desired process recipe. Alternatively, the vent time can be a predetermined amount of time (e.g., 10 seconds) less than the implant time to serve as a buffer time to avoid the loadlock venting being in the critical path. The determination of the implant time, for example, can be based on calculations based on the process recipe, historical implant times, and/or other times measured by or otherwise fed back to the controller 160.

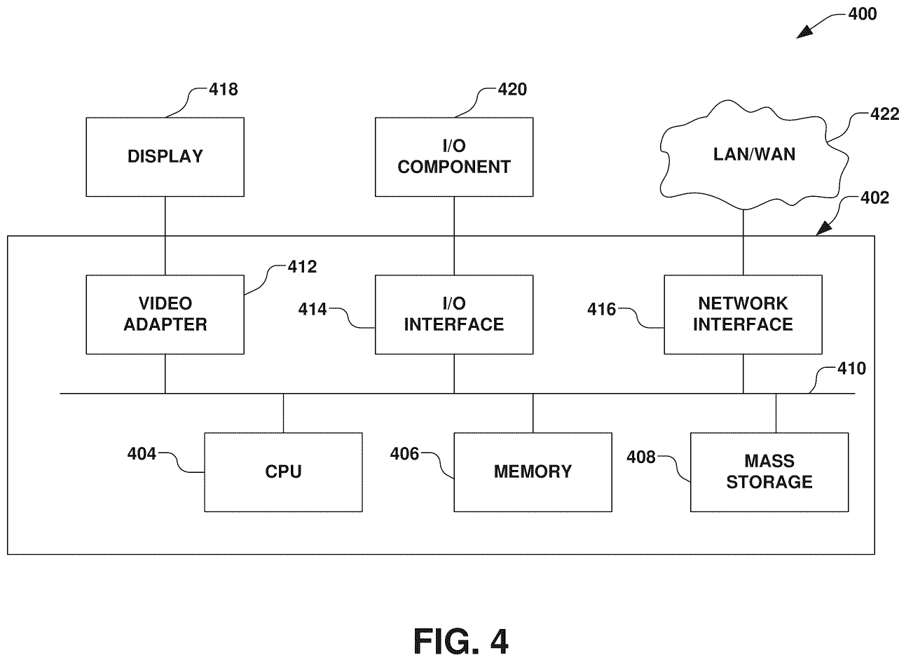

In accordance with another aspect, the aforementioned methodology may be implemented using computer program code in one or more of a controller, general purpose computer, or processor based system. As illustrated in FIG. 4, a block diagram is provided of a processor based system 400 in accordance with another embodiment. The processor based system 400 is a general purpose computer platform and may be used to implement processes discussed herein. The processor based system 400 may include a processing unit 402, such as a desktop computer, a workstation, a laptop computer, or a dedicated unit customized for a particular application. The processor based system 400 may be equipped with a display 418 and one or more input/output devices 420, such as a mouse, a keyboard, or printer. The processing unit 402 may include a central processing unit (CPU) 404, memory 406, a mass storage device 408, a video adapter 412, and an I/O interface 414 connected to a bus 410.

The bus 410 may be one or more of any type of several bus architectures including a memory bus or memory controller, a peripheral bus, or video bus. The CPU 404 may include any type of electronic data processor, and the memory 406 may include any type of system memory, such as static random access memory (SRAM), dynamic random access memory (DRAM), or read-only memory (ROM).

The mass storage device 408 may include any type of storage device configured to store data, programs, and other information and to make the data, programs, and other information accessible via the bus 410. The mass storage device 408 may include, for example, one or more of a hard disk drive, a magnetic disk drive, or an optical disk drive.

The video adapter 412 and the I/O interface 414 provide interfaces to couple external input and output devices to the processing unit 402. Examples of input and output devices include the display 418 coupled to the video adapter 412 and the I/O device 420, such as a mouse, keyboard, printer, and the like, coupled to the I/O interface 414. Other devices may be coupled to the processing unit 402, and additional or fewer interface cards may be utilized. For example, a serial interface card (not shown) may be used to provide a serial interface for a printer. The processing unit 402 also may include a network interface 416 that may be a wired link to a local area network (LAN) or a wide area network (WAN) 422 and/or a wireless link.

It should be noted that the processor based system 400 may include other components. For example, the processor based system 400 may include power supplies, cables, a motherboard, removable storage media, cases, and the like. These other components, although not shown, are considered part of the processor based system 400.

Embodiments of the present disclosure may be implemented on the processor based system 400, such as by program code executed by the CPU 404. Various methods according to the above-described embodiments may be implemented by program code. Accordingly, explicit discussion herein is omitted.

Further, it should be noted that various modules and devices in FIGS. 1-3 may be implemented on and controlled by one or more processor based systems 400 of FIG. 4. Communication between the different modules and devices may vary depending upon how the modules are implemented. If the modules are implemented on one processor based system 400, data may be saved in memory 406 or mass storage device 408 between the execution of program code for different steps by the CPU 404. The data may then be provided by the CPU 404 accessing the memory 406 or mass storage device 408 via bus 410 during the execution of a respective step. If modules are implemented on different processor based systems 400 or if data is to be provided from another storage system, such as a separate database, data can be provided between the systems through I/O interface 414 or network interface 416. Similarly, data provided by the devices or stages may be input into one or more processor based system 400 by the I/O interface 414 or network interface 416. A person having ordinary skill in the art will readily understand other variations and modifications in implementing systems and methods that are contemplated within the scope of varying embodiments.

Although the disclosure has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplified embodiments of the disclosure. In addition, while a particular feature of the disclosure may have been disclosed with respect to only one of several embodiments, such feature may be combined with one or more other features of the other embodiments as may be desired and advantageous for any given or particular application.

What is claimed is:

1. A workpiece processing system comprising:
a process chamber configured for processing a workpiece within a process environment at a vacuum pressure, whereby processing the workpiece defines a process time;
a loadlock chamber defining a loadlock volume therein, wherein the loadlock chamber comprises:
a vacuum isolation valve configured to provide selective fluid communication between the loadlock volume and the process environment, wherein the vacuum isolation valve is further configured to selectively permit the workpiece to transfer between the loadlock volume and the process environment; and
an atmospheric isolation valve configured to provide a selective fluid communication between the loadlock volume and an atmospheric environment at an atmospheric pressure, wherein the atmospheric isolation valve is further configured to selectively permit the workpiece to transfer between the loadlock volume and the atmospheric environment;
a vent gas control device configured to selectively control one or more of a pressure and a flow rate of a vent gas from a vent gas source to the loadlock volume, wherein a vent time is defined by a change from the vacuum pressure to the atmospheric pressure within the loadlock volume; and
a controller configured to control the vent gas control device based, at least in part, on a critical path defined by the longer of the process time and the vent time.

2. The workpiece processing system of claim 1, further comprising a pressure monitor configured to measure a loadlock pressure within the loadlock volume, and wherein the controller is further configured to control the vent gas control device based on the loadlock pressure.

3. The workpiece processing system of claim 1, wherein the controller is further configured to control the vent gas control device based on a plurality of process parameters associated with the process chamber and the loadlock chamber.

4. The workpiece processing system of claim 3, wherein the plurality of process parameters comprise one or more of a process recipe associated with processing the workpiece within the process environment and a characterization of the loadlock chamber, wherein the characterization of the loadlock chamber defines a minimum vent time.

5. The workpiece processing system of claim 4, further comprising an ion implantation system configured to process the workpiece by directing an ion beam toward the workpiece within the process chamber.

6. The workpiece processing system of claim 5, wherein the process recipe comprises one or more of an energy of the ion beam and a current of the ion beam.

7. The workpiece processing system of claim 5, wherein the process recipe comprises one or more of a desired beam current, a desired ion dose, a number of scans of the ion beam with respect to the workpiece, and an implant time during which the ion beam is directed toward the workpiece, thereby defining the process time.

8. The workpiece processing system of claim 7, wherein the controller is further configured to initially determine the implant time and the vent time based, at least in part, on the process recipe and the characterization of the loadlock chamber, and wherein the controller is further configured to maximize the vent time when the implant time is greater than the minimum vent time.

9. The workpiece processing system of claim 8, wherein the controller is further configured to minimize the vent time when the implant time is less than the minimum vent time.

10. The workpiece processing system of claim 7, wherein the ion implantation system is configured to provide feedback to the controller associated with a measured implant time, wherein the controller is further configured to control the vent time based on the feedback from the ion implantation system.

11. The workpiece processing system of claim 10, wherein the loadlock chamber is configured to provide feedback to the controller associated with one or more process parameters, and wherein the controller is further configured to determine the implant time and the vent time based on one or more process parameters associated with the ion implantation system.

12. The workpiece processing system of claim 4, wherein the minimum vent time comprises a predetermined buffer time added to the process time.

13. The workpiece processing system of claim 12, wherein the predetermined buffer time is one of a fixed amount of time and a percentage of the process time.

14. The workpiece processing system of claim 1, wherein the vent gas control device comprises one of a mass flow controller, a pressure flow controller, a pressure regulator, a velocity regulator, a needle valve.

15. The workpiece processing system of claim 1, wherein the controller is configured to minimize the flow rate concurrent with the change from the vacuum pressure to the atmospheric pressure.

16. A workpiece processing system comprising:
an ion implantation system configured define an ion beam based on a process recipe;
a workpiece chuck configured to selectively support a workpiece;
a process chamber configured to receive the ion beam, wherein the process chamber, wherein the process chamber is configured to define a process environment at a vacuum pressure therein, wherein the workpiece chuck is configured to selectively expose the workpiece to the ion beam within the process chamber for over a process time;
a loadlock chamber operably coupled to the process chamber and defining a loadlock volume therein, wherein the loadlock chamber comprises:
a vacuum isolation valve configured to provide selective fluid communication between the loadlock volume and the process environment, wherein the vacuum isolation valve is further configured to selectively permit a transfer of the workpiece between the loadlock volume and the process environment; and
an atmospheric isolation valve configured to provide a selective fluid communication between the loadlock volume and an atmospheric environment at an atmospheric pressure, wherein the atmospheric isolation valve is further configured to selectively permit a transfer of the workpiece between the loadlock volume and the atmospheric environment;
a vent gas source selectively fluidly coupled to the loadlock chamber and configured to provide selectively provide a vent gas thereto;
a vent gas control device configured to selectively control one or more of a pressure and a flow rate of the vent gas from the vent gas source to the loadlock volume, wherein a vent time is defined by a change from the vacuum pressure to the atmospheric pressure within the loadlock volume; and
a controller configured to control the vent gas control device based, at least in part, on a critical path defined by the longer of the process time and the vent time.

17. The workpiece processing system of claim 16, wherein the controller is further configured to control the vent gas control device based on one or more of the process recipe and a characterization of the loadlock chamber, wherein the characterization of the loadlock chamber defines a minimum vent time.

18. The workpiece processing system of claim 17, wherein the controller is further configured to initially determine the process time and the vent time based, at least in part, on the process recipe and the characterization of the loadlock chamber, and wherein the controller is further configured to maximize the vent time when the process time is greater than the minimum vent time.

19. The workpiece processing system of claim 18, wherein the controller is further configured to minimize the vent time when the process time is less than the minimum vent time.

20. The workpiece processing system of claim 17, wherein the process recipe comprises one or more of a desired beam current, a desired ion dose, a number of scans of the ion beam with respect to the workpiece.

21. A method for optimizing a processing of a workpiece, the method comprising:
identifying parallel processes in a workpiece processing system, wherein the parallel processes comprise at least an exposure of the workpiece to a process medium at a vacuum pressure in a process chamber and a venting of a loadlock chamber from the vacuum pressure to atmospheric pressure via a vent gas to define a vent time;
determining a process time associated with the exposure of the workpiece to the process medium at the vacuum pressure;
determining a minimum vent time associated with the venting of the loadlock chamber from the vacuum pressure to the atmospheric pressure, wherein the minimum vent time is associated with a predetermined maximum flow rate of the vent gas through the loadlock chamber;
determining a critical path of the parallel processes based on a comparison of at least the process time and the minimum vent time; and
controlling one or more of a pressure and a flow rate of the vent gas to maximize the vent time when the minimum vent time is less than the process time while maintaining the vent time at less than the process time, and to minimize the vent time when the process time is greater than the minimum vent time while maintaining the vent time at greater than the minimum vent time.
